(19) United States
(12) Patent Application Publication
(10) Pub. No.: US 2026/0256034 A1
(43) Pub. Date: Aug. 27, 2026

(54) SEMICONDUCTOR STACK FORMATION WITH REUSABLE CARRIERS

(71) Applicant: Micron Technology, Inc., Boise, ID (US)

(72) Inventor: Wei Zhou, Boise, ID (US)

(21) Appl. No.: 19/540,207

(22) Filed: Feb. 13, 2026

Related U.S. Application Data
(60) Provisional application No. 63/763,129, filed on Feb. 25, 2025.

(51) Int. Cl. H10W 90/00; H10W 74/10

(52) U.S. Cl. CPC H10W 90/734; H10W 74/117; H10W 90/00

(57) ABSTRACT

Methods, systems, and devices for semiconductor stack formation with reusable carriers are described. A semiconductor system may be fabricated based on bonding a first surface of a first semiconductor component with a carrier using an adhesive material. The first semiconductor component may include one or more conductor portions along the first surface, which may be coupled with first circuitry of the first semiconductor component. A second semiconductor component may be bonded with a second surface of the first semiconductor component, and the first circuitry of the first semiconductor component may be electrically coupled with second circuitry of the second semiconductor component. A second conductor material may be formed in contact with the first conductor material based on removing the first semiconductor component and the second semiconductor component from the carrier and the adhesive material.

### CROSS REFERENCE

The present Application for Patent claims priority to U.S. Patent Application No. 63/763,129 by Zhou et al., entitled “SEMICONDUCTOR STACK FORMATION WITH REUSABLE CARRIERS,” filed February 25, 2025, which is assigned to the assignee hereof, and which is expressly incorporated by reference in its entirety herein.

### TECHNICAL FIELD

The following relates to one or more semiconductor systems, including semiconductor stack formation with reusable carriers.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports semiconductor stack formation with reusable carriers in accordance with examples as disclosed herein.

FIG. 2 shows an example of a system that supports semiconductor stack formation with reusable carriers in accordance with examples as disclosed herein.

FIG. 3 shows an example of a system that supports semiconductor stack formation with reusable carriers in accordance with examples as disclosed herein.

FIG. 4A through 4H illustrate examples of fabrication operations that support semiconductor stack formation with reusable carriers in accordance with examples as disclosed herein.

FIG. 5 shows a flowchart illustrating a method or methods that support semiconductor stack formation with reusable carriers in accordance with examples as disclosed herein.

### DETAILED DESCRIPTION

Some semiconductor systems (e.g., memory systems, processor systems, systems having a combination of memory and processing) may include a stack of semiconductor components (e.g., semiconductor dies), which may include one or more memory dies (e.g., memory dies, array dies, memory array dies) or one or more stacks of memory dies that are stacked with a logic die that is operable to access a set of memory arrays distributed across the one or more memory dies. Such a stacked architecture may be implemented as part of a high bandwidth memory (HBM) system or a coupled dynamic random access memory (DRAM) system, among other examples, and may support solutions for memory-centric logic, such as graphics processing units (GPUs), among other implementations. In some examples, an HBM system may include one or more memory dies coupled (e.g., bonded, stacked) with a logic die. In some examples, a 3D stacked memory system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

Some techniques for fabricating a semiconductor system (e.g., an HBM system, a 3D stacked memory system) may utilize one or more carrier materials, such as for temporary mounting or to facilitate bonding of semiconductor components. In some cases, carriers may be “sacrificial,” meaning that the carriers may be dismantled (e.g., partially or wholly) as part of a fabrication process (e.g., after die bonding occurs). As such, usage of these carriers may be limited (e.g., as a one-time use) contributing to inefficiencies and potentially adverse environmental impacts of the fabrication process. Moreover, implementing sacrificial carriers may involve additional fabrication operations to support bonding with semiconductor components such as the formation of additional bonding layers (e.g., fusion bonding dielectric materials), cleaning operations, passivation operations, or combinations thereof. Such operations may increase fabrication complexity, reduce system reliability, and increase fabrication cost.

In accordance with one or more techniques described herein, a semiconductor system (e.g., a stacked semiconductor system or other electronic devices) may be fabricated utilizing methods that enable reusable carriers. For example, an adhesive material (e.g., glue) may be applied to a surface of a reusable carrier material (e.g., glass), and the adhesive material may support a direct bonding (e.g., thermocompression bonding (TCB)) of the reusable carrier with a surface of a semiconductor component (e.g., a semiconductor wafer, a semiconductor die). Such adhesive material bonding techniques may simplify surface preparation for bonding operations (e.g., in comparison to other carrier bonding techniques, such as fusion bonding), which may reduce fabrication complexity, reduce cost, and increase reliability of the semiconductor system. For example, an original surface of a semiconductor component may be ready for carrier bonding without the formation of additional bonding layers. Moreover, by utilizing an adhesive bonding, the carrier may be reused (e.g., recycled) in subsequent fabrication cycles. For example, after a bonding operation, the adhesive may be removed from the semiconductor component surface and from the carrier surface, and the carrier may be used for another fabrication process (e.g., and bonded with another device). Thus, the one or more techniques herein may reduce material waste, reduce fabrication cost and complexity, and contribute to a more sustainable approach for semiconductor fabrication with reduced environmental impact.

In addition to applicability in memory systems as described herein, techniques for semiconductor stack formation with reusable carriers may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing materials used in production of electronic devices and eliminating production processes, which may result in lowered production emissions and reduce electronic waste, among other benefits.

Features of the disclosure are illustrated and described in the context of systems and architectures. Features of the disclosure are further illustrated and described in the context of devices, operations, and flowcharts.

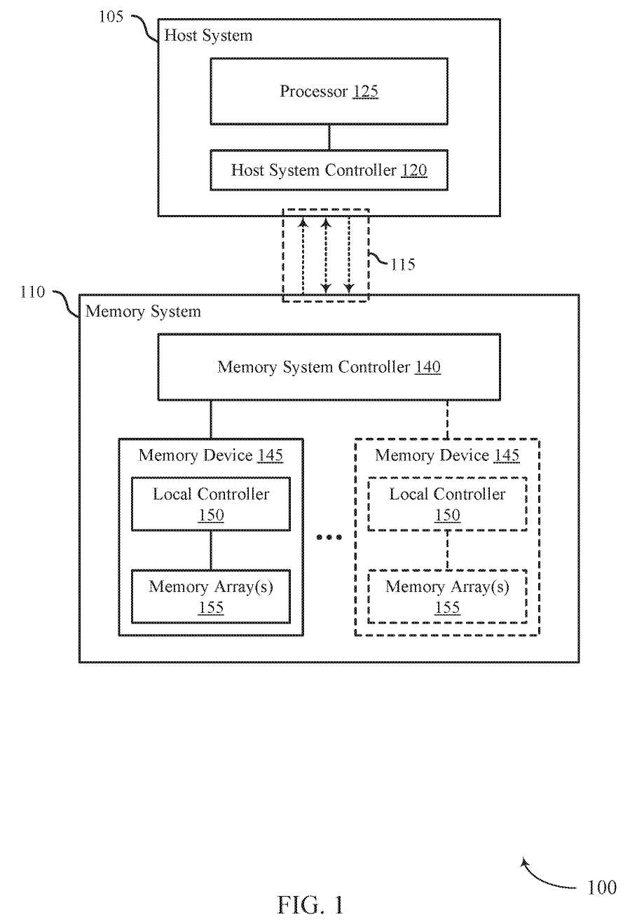

FIG. 1 shows an example of a system 100 that supports semiconductor stack formation with reusable carriers in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

In some examples, the system 100 or a host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of a system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks, or in one or more other dies. In some examples, multiple semiconductor dies of a memory system 110 or of a system 100 (e.g., an HBM system including aspects of a memory system 110, a 3D stacked memory system including aspects of a memory system 110 and a host system 105) may include one or more array dies stacked with one or more logic dies (e.g., that include aspects of the host system 105, that is coupled with another set of one or more dies that includes the host system 105) that includes interface blocks operable to access a set of memory arrays 155 distributed across the one or more second dies.

Some techniques for fabricating a system 100 or a portion thereof (e.g., a semiconductor device portion) may utilize one or more sacrificial carrier materials. For example, a carrier may be destroyed (e.g., at least in part) as part of a fabrication process, contributing to the overall inefficiency and environmental impact of the fabrication process. Moreover, the use of sacrificial carriers may involve additional fabrication operations to support bonding with semiconductor components (e.g., a host system 105 or portions thereof, a memory system 110 or portions thereof, a memory device 145 or portions thereof), such as the deposition of additional bonding layers, additional cleaning operations, and passivation operations. Such additional operations may increase fabrication complexity, increase an environmental impact, and increase fabrication cost.

In accordance with one or more techniques described herein, a semiconductor portion of a system 100, or portion of a system 100 (e.g., a host system 105, a processor 125, a host system controller 120, a memory system 110, a memory system controller 140, a memory device 145) may be fabricated utilizing methods that enable reusable carriers. For example, an adhesive material (e.g., glue) may be applied to a surface of a reusable carrier material (e.g., glass), and the adhesive material may support a direct bonding (e.g., a TCB operation) of the reusable carrier with a surface of a semiconductor component (e.g., a semiconductor wafer, a semiconductor die). These adhesive material bonding techniques may be associated with reduced fabrication complexity, reduced cost, and increased reliability of the semiconductor system (e.g., based on the reduction of fabrication operations and material formation). Moreover, by utilizing an adhesive bonding, the carrier may be reused in subsequent fabrication cycles, which may result in reduced waste. As such, the one or more techniques herein may improve fabrication methods by reducing waste, reducing cost and complexity, and may provide a more sustainable approach to semiconductor fabrication.

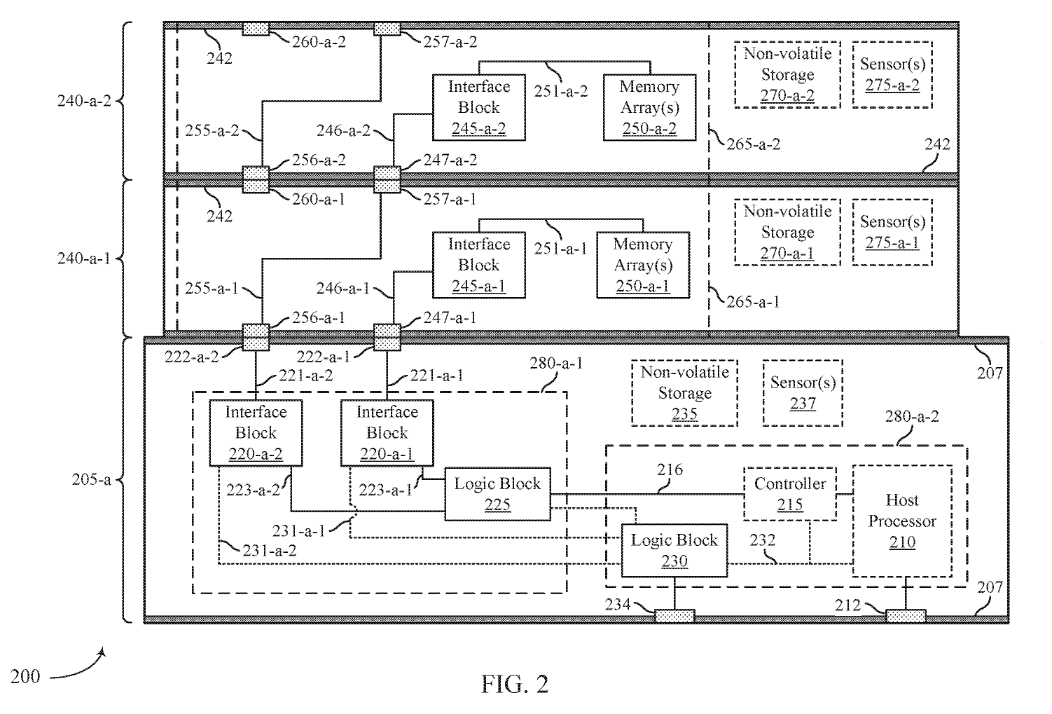

FIG. 2 shows an example of a system 200 (e.g., a semiconductor system, a system of coupled semiconductor dies, an HBM system, a 3D stacked memory system) that supports semiconductor stack formation with reusable carriers in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units, of a memory stack). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g.,

divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations (e.g., 3D stacked memory implementations), a die 205 may include a host processor 210. A host processor 210 may be an example of a host system 105, or a portion thereof (e.g., a processor 125, aspects of a host system controller 120, or both). A host processor 210 may include one or more processor cores that are configured to perform operations that implement storage of the memory arrays 250 (e.g., to support an application or other function of a host system 105, which may request access to the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in a 3D stacked memory implementation, in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth configuration of the system 200, in accordance with a closely-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220 (e.g., in accordance with a command and address protocol). The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more through-silicon vias (TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205-a with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube,” a memory stack, or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

Some techniques for fabricating a system 200 or a portion thereof may utilize one or more sacrificial carrier materials. For example, a carrier may be destroyed (e.g., at least in part) as part of a fabrication process (e.g., after bonding a die 240-a-1 with a die 240-a-2, after bonding one or more dies 240 with a die 205), contributing to the overall inefficiency and adverse environmental impact. Moreover, the use of sacrificial carriers may involve additional fabrication operations (e.g., for forming a die 240 or wafer of dies 240, for forming a die 205 or a wafer of dies 205) to support bonding with semiconductor components, such as the deposition of additional bonding layers (e.g., fusion bonding dielectric materials), additional cleaning operations, and passivation operations. Such additional operations may increase fabrication complexity, increase an environmental impact, and increase fabrication cost.

In accordance with one or more techniques described herein, a system 200, or portion thereof, may be fabricated utilizing methods that enable reusable carriers. For example, an adhesive material (e.g., glue) may be applied to a surface of a reusable carrier material (e.g., glass), and the adhesive material may support a direct bonding (e.g., a TCB operation) of the reusable carrier with a surface of a semiconductor component (e.g., or another electronic device). These adhesive material bonding techniques may be associated with reduced fabrication complexity, reduced cost, and increased reliability of the system 200 (e.g., based on the reduction of fabrication operations and material formation). Moreover, by utilizing an adhesive bonding, the carrier may be reused in subsequent fabrication cycles, which may result in reduced waste. As such, the one or more techniques herein may improve fabrication methods by reducing waste, reducing cost and complexity, and may provide a more sustainable approach to semiconductor fabrication.

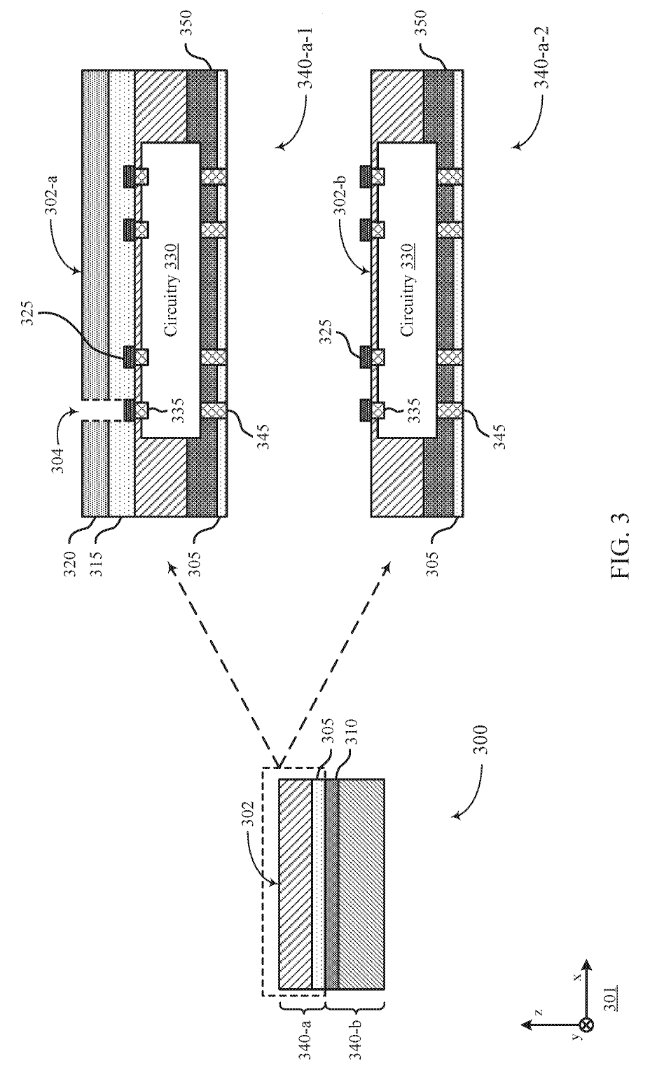

FIG. 3 shows an example of a system 300 that supports semiconductor stack formation with reusable carriers in accordance with examples as disclosed herein. The system 300 (e.g., a semiconductor system, a semiconductor apparatus, a 3D DRAM stack, a 3D stacked memory, an HBM “twinlet”) may be an example of or include one or more aspects of a system 100 or a system 200, and may be described with reference to an x-direction, a y-direction, and a z-direction of a coordinate system 301. The system 300 may include a stack of components 340 (e.g., semiconductor components, semiconductor wafers, semiconductor dies, logic dies, memory array dies, core dies, DRAM dies) such as the component 340-a (e.g., core 1) and the component 340-b (e.g., core 2). A component 340 may, in some cases, be an example of or include a die 240 or wafer of dies, or a die 205 or wafer of dies 205, among other examples. Although a system 300 may implement dies 205 and dies 240, the described techniques may be implemented in accordance with other types of semiconductor components, electronic devices, or combinations thereof.

The system 300 may illustrate an example of an “twinlet” die stack, which may refer to a stack that includes at least two components 340 (e.g., two DRAM dies). Moreover, the techniques herein may be applicable for stacks different than shown in the non-limiting example of FIG. 3, including stacks that include three or more components 340. The component 340-a and the component 340-b may be bonded via hybrid bonding (e.g., supporting a communicative coupling between respective circuitry of the components 340), such as in a front side-to-back side (e.g., front-to-back (F2B)) configuration. For example, a front side (e.g., an active side) of the component 340-b may include a dielectric material 310 and one or more first conductive contacts (e.g., through the dielectric material 310, contacts 257, contacts 260, contacts 222, not shown) to support the hybrid bonding. Further, a back side (e.g., a side opposite an active side) of the component 340-a may include a dielectric material 305 and one or more second conductive contacts 345 (e.g., through the dielectric material 305, contacts 247, contacts 256) that are respectively bonded (e.g., at a bonding interface) with the dielectric material 310 and the first contacts of the component 340-b.

In some cases, prior to bonding with each other, at least one of the components 340 may have been bonded with a carrier (e.g., a sacrificial silicon carrier, not shown). For example, the component 340-a may have been previously bonded with a carrier at a surface 302-a. Some fabrication methods may utilize fusion bonding techniques for carrier bonding, which may implement a fusion of respective dielectric material layers, or bonding layers, at the carrier and at the component 340, and such dielectric materials may remain at the surface 302-a after removal of the carrier. As an illustrative example, the component 340-a-1 may show an expanded view of a component 340-a after removal of a fusion-bonded carrier (e.g., via grinding, polishing, etching, cutting, or some other operation). After carrier removal, one or more bonding layers may remain over the component 340-a-1, including a dielectric material 315 (e.g., a bonding layer of the component 340-a-1), a dielectric material 320 (e.g., a bonding layer that remains from a removed carrier), or both.

In some examples, additional dielectric materials may cover one or more conductors 325 (e.g., conductor portions, contacts, pads, contacts 222, 247, 256, 257, or 260) that are used to access circuitry 330 (e.g., interface blocks 245, memory arrays 250, non-volatile storage 270, sensors 275, interface blocks 220, logic block 225, unit 280, non-volatile storage 235, one or more sensors 237, or other semiconductor circuitry). The conductors 325 may be coupled with the circuitry 330 based on one or more vias 335, which may refer to vias formed during a back-end-of-line (BEOL) process, during a middle of line (MOL) process, or during a front end-of-line (FEOL) process, or in some other examples, may refer to through-substrate vias (e.g., TSVs). In some examples, the circuitry 330 may be coupled with circuitry of other components 340 (e.g., the component 340-b) based on one or more contacts 345 (e.g., including or coupled with TSVs or, in some other examples, vias of a BEOL or FEOL process), which may be formed through a substrate 350 (e.g., a semiconductor substrate including a doped silicon portion of the circuitry 330) and through the dielectric material 305.

In some examples, to expose the conductors 325 to provide a functional interconnection, additional operations may be performed, such as forming one or more cavities 304 through the dielectric material 315 and the dielectric material 320, and forming one or more conductive materials along the cavity and to or above the surface 302-a. Moreover, the fusion bonding of the dielectric material 315 with the dielectric material 320 may rely on additional surface preparation to ensure smooth, particle-free bonding surfaces. These additional operations may add complexity to the fabrication process and may potentially affect the reliability of the component 340-a-1 (e.g., by introducing additional particle debris based on forming the cavities 304 or carrier edge trimming).

In accordance with techniques herein, a system 300 may be fabricated in a manner that supports reusable carriers. For example, an adhesive material (e.g., glue) may be applied to a reusable carrier material (e.g., glass). The adhesive material may support a direct bonding (e.g., via TCB) of the reusable carrier with a surface 302 of a component 340-a. As an illustrative example, the component 340-a-2 may show an expanded view of a component 340-a after removal of a reusable carrier. For example, after the component 340-a-2 is bonded with a component 340-b, the reusable carrier may be removed from the component 340-a-2 (e.g., and from the adhesive) and the carrier may remain intact after the removal (e.g., for coupling with a different component 340-a to support bonding with another component 340-b). The adhesive material may also be removed from the surface 302-b. Such adhesive bonding may not involve the use of additional dielectric materials (e.g., dielectric materials 315 and 320) to facilitate the carrier bonding. As such, after the carrier and adhesive are removed, the surface 302-b may be the same as or more similar to when the component 340-a-2 was fabricated (e.g., a wafer surface may be same as after original fabrication of the component 340-a-2, additional dielectric materials may not be included at the surface, without a layer of bonding oxide being formed). For example, the surface 302-b (e.g., a wafer surface) may have one or more conductors 325 (e.g., aluminum pads) that are exposed after the carrier and adhesive removal.

Thus, by applying one or more techniques herein, systems 300 may be fabricated with reduced complexity (e.g., as shown by the non-limiting example of the component 340-a-2), which may reduce fabrication cost and increase reliability of the system 300. Moreover, the described techniques may enable the use of reusable (e.g., recycled) carrier materials, which may be used as part of multiple fabrication cycles. The use of recyclable carrier material may thus contribute to reduced material usage and reduced waste, thereby enabling increased fabrication efficiency and reduced adverse environmental effects from fabricating systems 300 and other electronic devices.

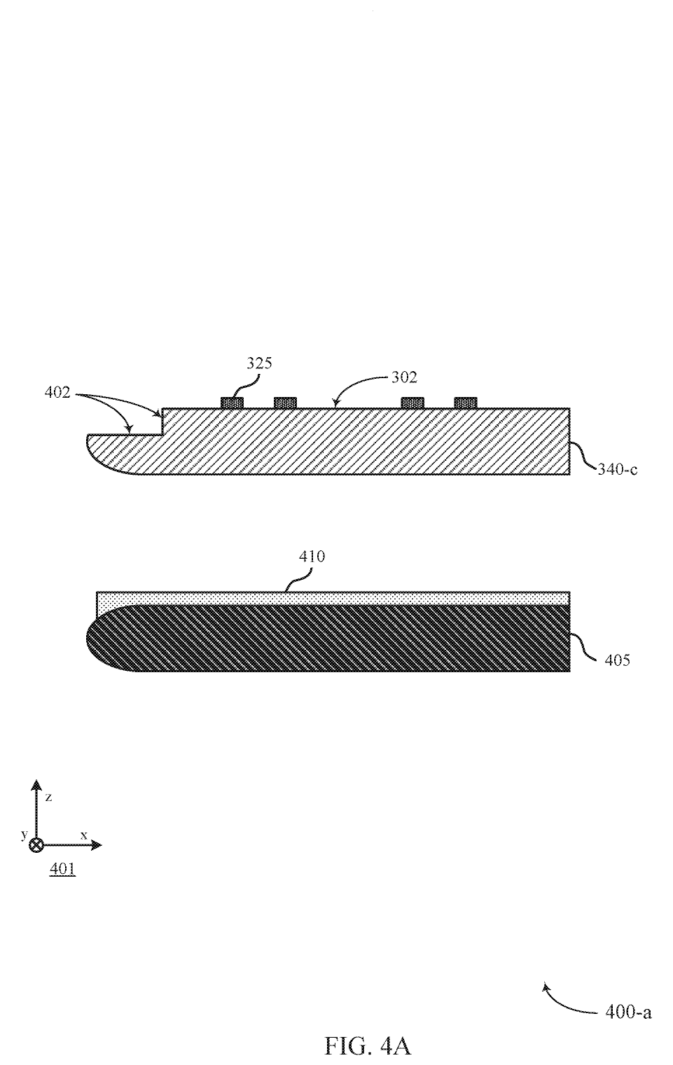

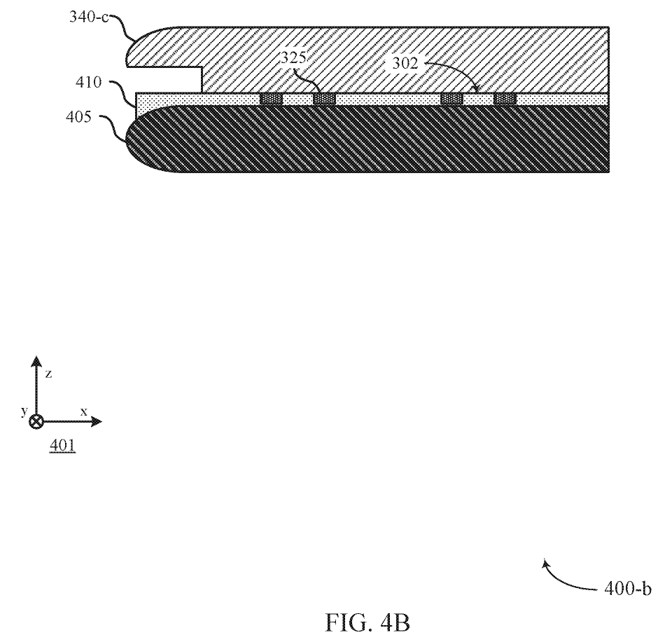

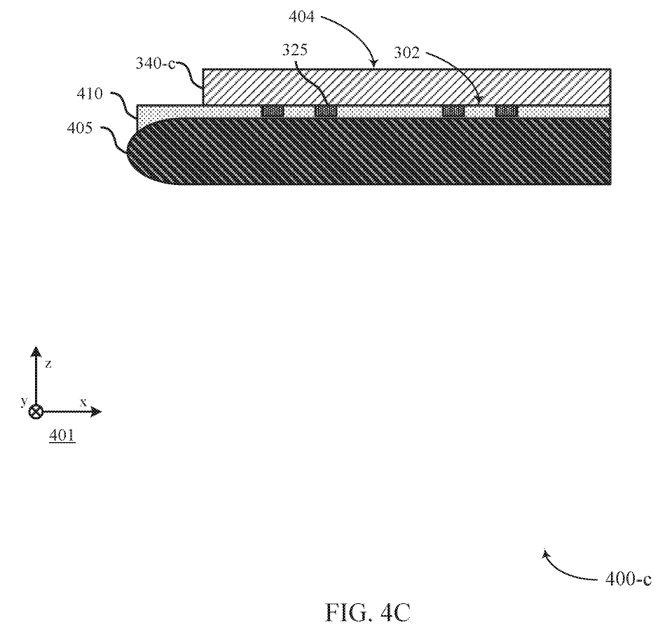

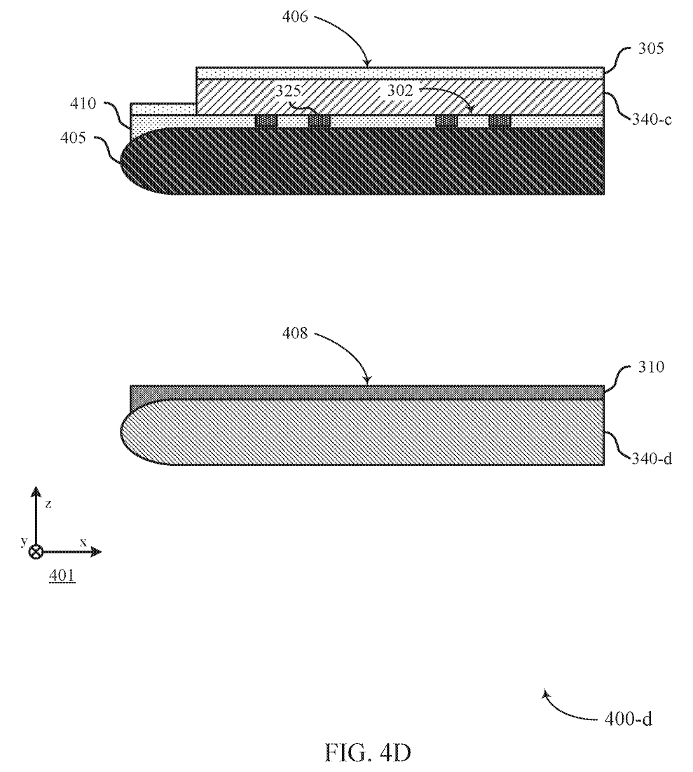

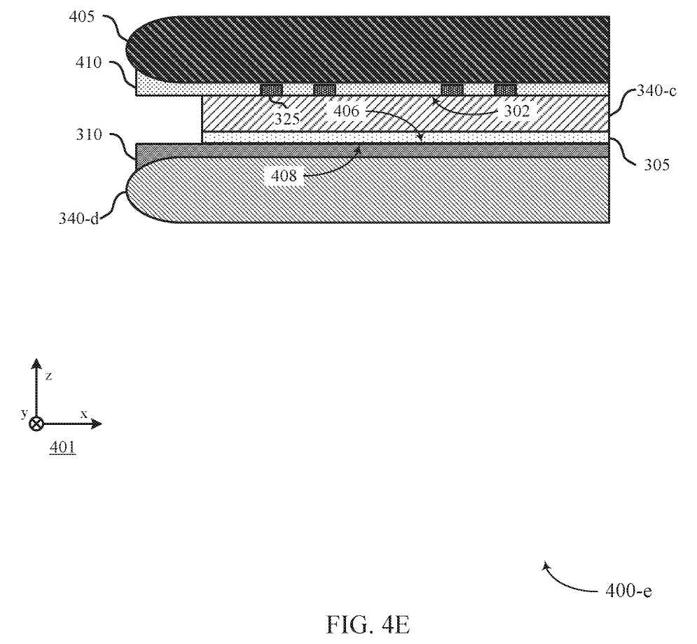

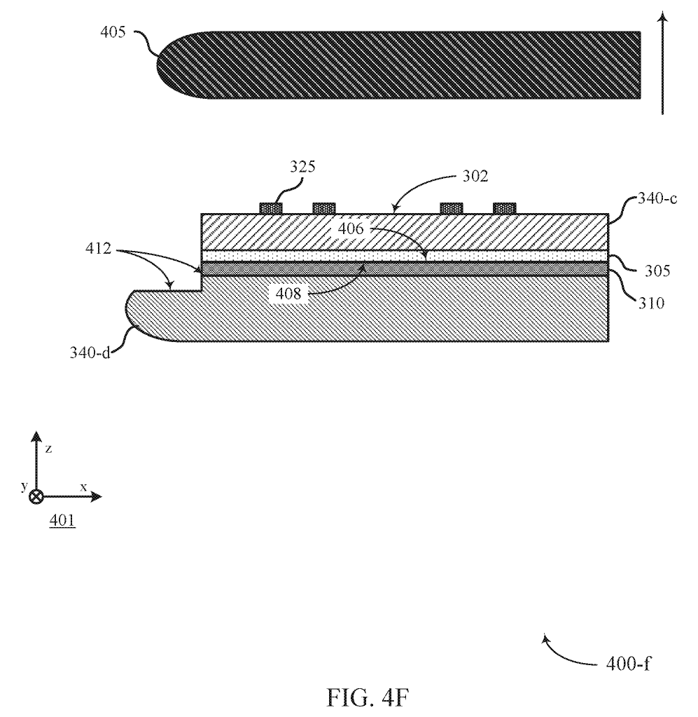

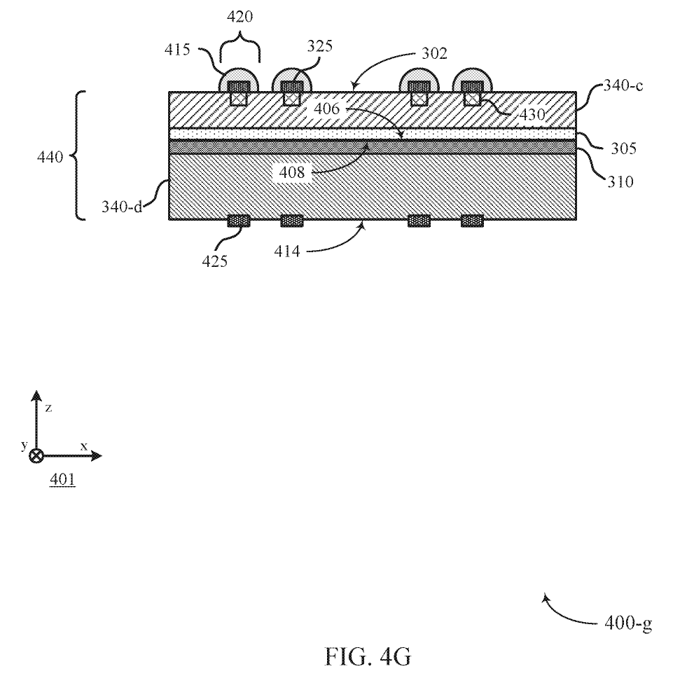

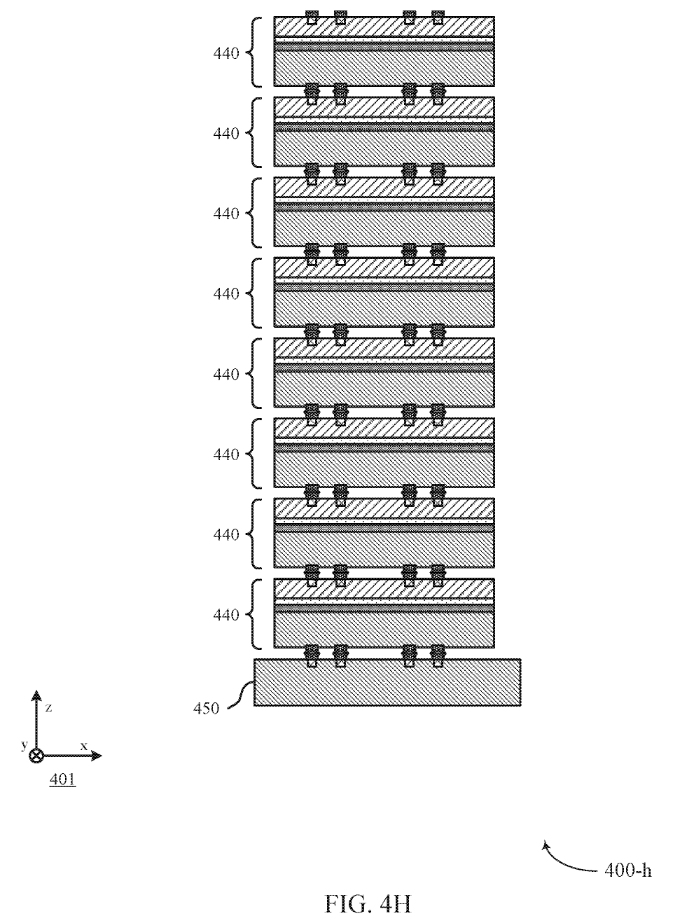

FIGS. 4A through 4D illustrate examples of semiconductor stack formation with reusable carriers in accordance with examples as disclosed herein. Operations are illustrated with reference to a system 400 (e.g., a semiconductor system, a semiconductor apparatus, a semiconductor stack, a semiconductor device, a semiconductor subcomponent), which may be an example of or include an electronic device (e.g., a system 100, a memory system 110, a host system 105, a system 200, a system 300), or a portion thereof. For example, FIGS. 4A through 4G may illustrate aspects of a sequence of operations that support manufacturing a system 100 or a portion thereof, a system 200 or a portion thereof, a system 300 or a portion thereof, or some other device.

Each of FIGS. 4A through 4G may illustrate aspects of the system 400 after different subsets of the fabrication operations for forming the system 400 (e.g., illustrated as a system 400‑a after a first set of one or more fabrication operations, as a system 400‑b after a second set of one or more fabrication operations, and so on). Each view of FIGS. 4A through 4G may be described with reference to an x-direction, a y-direction, and a z-direction of a coordinate system 401. For example, aspects of the system 400 may be illustrated in accordance with a cut plane (e.g., along an xz-plane) to show embedded features of the system 400. Although, FIGS. 4A through 4G illustrate examples quantities of various features and example dimensionality, the techniques described herein may be applicable for various configurations of such aspects, including greater quantities than shown, fewer quantities than shown, and different dimensionality than shown.

Operations illustrated in and described with reference to FIGS. 4A through 4G may be performed by a manufacturing system, such as a semiconductor fabrication system configured to perform additive operations (e.g., deposition, epitaxy, bonding), subtractive operations (e.g., etching, trenching, planarizing, polishing, trimming), modifying operations (e.g., oxidizing, doping, reacting, converting), and supporting operations (e.g., masking, patterning, photolithography, aligning), among other operations that support the described techniques for formation of the features of the system 400. In some examples, operations performed by such a manufacturing system may be supported by a process controller or its components as described herein (e.g., including instructions stored in a non-transitory computer-readable medium that are executable by a processing system to cause the manufacturing system to perform the operations).

In some examples, portions of the system 400 that are illustrated with a same fill pattern may be formed of same or similar materials and portions that are illustrated with different patterns may be formed of different materials. Various material layers are described herein, which may include an aluminum nitride, a silicon carbide, a silicon oxide, a silicon nitride, a silicon carbon nitride, a tetraethyl orthosilicate (TEOS), a boron arsenide, some other dielectric material such as some other oxide or nitride material, or any combination thereof. Additionally, conductive materials described herein may include copper, aluminum, tungsten, titanium, solder, some other conductive material, or any combination thereof.

FIG. 4A shows an example of a cross-sectional view of a system 400-a after a first set of one or more fabrication operations. For example, the first operations may include providing (e.g., forming, preparing) a component 340-c (e.g., a semiconductor component, an example of a component 340-a-2), which may be formed as a wafer that includes multiple dies for later singulation (e.g., multiple components 340-c as semiconductor dies having a common substrate 350). In some examples, the component 340-c may include one or more conductors 325 (e.g., conductor portions, conductive contacts) along a surface 302 (e.g., along an xy-plane) and coupled with circuitry (e.g., circuitry 330, not shown) of the component 340-c. The component 340-c may include additional features not shown, such as circuitry 330, vias 335, contacts 345, substrate 350, or other features described herein. In some examples, the first operations may include refraining from forming a bonding layer (e.g., omitting a dielectric material 315 that may be otherwise implemented for fusion bonding with a carrier in accordance with other techniques, leaving conductors 325 exposed) at the surface 302 of the component 340-c.

The first operations may also include forming (e.g., applying, depositing) an adhesive material 410 (e.g., glue) over a surface of a carrier 405 (e.g., a reusable carrier). In some examples, the carrier 405 may be formed of (e.g., include) a glass material or some other reusable material. For example, the carrier 405 may have been used for other fabrication operations prior to the first operations. In some examples, the first operations may include performing an edge trim operation to remove a portion of the component 340-c (e.g., exposing one or more edges 402) before bonding the component 340-c with the carrier 405. In some examples, an “edge trim” may refer to a process of removing excess material (e.g., by mechanical grinding, laser cutting, or chemical etching) from the edges of a component 340 (e.g., as a wafer, as a die) during fabrication to ensure that the edges are smooth and free of defects and may prevent issues such as cracking or contamination during subsequent processing steps.

FIG. 4B shows an example of a cross-sectional view of a system 400-b after a second set of one or more fabrication operations. For example, the second operations may include bonding the surface 302 of the component 340-c with the carrier 405 using the adhesive material 410. In some examples, a conductor material of the conductors 325 may be in contact (e.g., direct contact, covered) with the adhesive material 410. In some examples, bonding the surface 302 of the component 340-c with the carrier 405 may include a TCB of the surface 302 with the adhesive material 410. In some examples, bonding the component 340-c with the carrier 405 may be supported by (e.g., based on) an absence of the bonding layer at the surface 302 (e.g., may be a direct bonding with the materials at the surface 302, without a dielectric material 315, without a dielectric material 320). In some examples, these bonding operations may be associated with reduced (e.g., less stringent) surface preparation prior to the bonding. For example, the bonding may occur in absence of a cleaning operation or a passivation operation, which may be implemented in other techniques that involve a fusion between a dielectric material 315 and a dielectric material 320.

FIG. 4C shows an example of a cross-sectional view of a system 400-c after a third set of one or more fabrication operations. For example, the third operations may include removing a portion of the component 340-c to expose one or more contacts (e.g., contacts 345, not shown) along a surface 404 (e.g., a TSV reveal operation, a back side reveal). The removal may involve a chemical-mechanical polishing (CMP) or other planarizing operation that removes material of the component 340-c along the negative z-direction to establish the surface 404 at a particular depth (e.g., that exposes the contacts). In some examples, bonding the component 340-c with other components may be based on exposing the one or more contacts. In some examples, the third operations may include refraining from performing an edge trim operation on the carrier 405 (e.g., to support the reusability of the carrier 405).

FIG. 4D shows an example of a cross-sectional view of a system 400-d after a fourth set of one or more fabrication operations. For example, the fourth operations may include providing (e.g., forming, preparing) a component 340-d (e.g., a semiconductor component, an example of a component 340-b), which may be formed as a wafer that includes multiple dies for later singulation (e.g., multiple components 340-d as semiconductor dies having a common substrate 350). The component 340-d may include additional features not shown, such as circuitry, vias, substrate materials, or other features described herein.

The fourth operations may also include forming, a dielectric material 305 along the surface 404 (e.g., over a back side of the component 340-c), which may form a surface 406 (e.g., a bonding surface of the component 340-c). The component 340-d may include, or the fourth operations may include forming, a dielectric material 310 (e.g., over a front side of the component 340-d), which may form a surface 408 (e.g., a bonding surface of the component 340-d).

FIG. 4E shows an example of a cross-sectional view of a system 400-e after a fifth set of one or more fabrication operations. For example, the fifth operations may include bonding the component 340-d (e.g., the surface 408) with the component 340-c (e.g., with the surface 406, which may be opposite the surface 302). In some examples, first circuitry of the component 340-c may be electrically coupled with second circuitry of the component 340-d based on bonding the component 340-d with the component 340-c (e.g., in accordance with a hybrid bonding of respective contacts that extend through dielectric materials 305 and 310, based on one or more contacts, or other interfacing circuitry, of each component 340). In some examples, the first circuitry may include first memory array circuitry (e.g., memory arrays 250, memory devices 145) and the second circuitry may include second memory array circuitry. In some examples, the surface 406 may include the dielectric material 305 and the surface 408 may include the dielectric material 310.

In some examples, bonding the component 340-d with the component 340-c may be based on a fusion of the dielectric material 310 (e.g., at the front side of the component 340-d) with the dielectric material 305 (e.g., at the back side of the component 340-c, via front-to-back hybrid bonding). Additionally, or alternatively, the bonding may be based on a fusion of one or more conductive contacts of each component 340 (e.g., in hybrid bonding implementation or a solder bond implementation). In some examples, the component 340-c may be associated with (e.g., be part of) a first wafer that includes multiple components 340-c and the component 340-d may be associated with (e.g., be part of) a second wafer that includes components 340-d. In such examples, bonding the component 340-d with the component 340-c may be based on bonding the first wafer with the second wafer (e.g., in accordance with a wafer-to-wafer bonding).

FIG. 4F shows an example of a cross-sectional view of a system 400-f after a sixth set of one or more fabrication operations. For example, the sixth operations may include removing the carrier 405 from the system 400 (e.g., in accordance with a glass debond operation) and removing the adhesive material 410 (e.g., in accordance with a glue removal operation). As such, the surface 302 may appear the same as when the component 340-c (e.g., the wafer) was originally provided (e.g., as fabricated). For example, the removal of the carrier 405 and the adhesive material 410 may expose the conductors 325 (e.g., as fabricated during formation of the component 340-c). In some examples, the sixth operations may include performing an edge trim operation to remove a portion of the component 340-d (e.g., exposing one or more edges 412) after removing the bonded components 340-c and 340-d from the carrier 405 and the adhesive material 410.

In some examples, the carrier 405 may, after being removed from the bonded components 340-c and 340-d, be bonded with another semiconductor component (e.g., another component 340 not shown, or another device). For example, the carrier 405 may be reused (e.g., recycled) for a subsequent fabrication process (e.g., for bonding with another component 340 different than the components 340-c and 340-d). Such reuse may, for example, use a second adhesive material to bond the carrier 405 with another component. By enabling the reuse of carriers 405, fabrication of systems 400 as described herein may be associated with reduced waste, reduced cost, and reduced adverse environmental impact, among other benefits.

FIG. 4G shows an example of a cross-sectional view of a system 400-g after a seventh set of one or more fabrication operations. For example, the seventh operations may include forming a conductor material 415 in contact with the one or more conductors 325, which may form one or more conductor portions 420. In some examples, the conductors 325 may include aluminum and the conductor material 415 may include a solder material. Although, in some examples (e.g., as illustrated), the conductor material 415 may be in contact with the surface 302, in some other examples, the conductor material 415 may extend (e.g., along the z-direction) from the top surface of the contacts 325 without contacting the surface 302 (e.g., as a conductor stack, to form solder bumps extending from the surface 302).

The seventh operation may also include forming (e.g., exposing, planarizing, etching, in accordance with a back side reveal) one or more conductors 425 (e.g., pads), which may include a same material as the conductors 325 (e.g., aluminum) or may include a different material (e.g., nickel). The conductors 425 may be formed (e.g., located, exposed) along a surface 414 of the component 340-d opposite the surface 408 that is bonded with the component 340-c (e.g., with the surface 406). In some examples, the seventh operations may include one or more post wafer fabrication (PWF) operations such as testing, singulation (e.g., dicing), packaging, and other backend processes. For example, the system 400 may be isolated (e.g., diced, singulated) from other systems of the bonded wafers as part of the seventh operations (e.g., and may be individually evaluated to identify potential defects). In some examples, such techniques may be associated with forming a component 440 (e.g., a die stack, an example of a system 300, a “twinlet”) including two semiconductor dies FIG. 4H shows an example of a cross-sectional view of a system 400-h after an eighth set of one or more fabrication operations. For example, the eighth operations may include bonding (e.g., soldering) multiple components 440 in a stack. In the example of system 400-h, eight components 440 are bonded in a stack (e.g., along the z-direction), which may support a 16-high HBM or 3D stacked memory implementation (e.g., for which each component 440 includes two dies 240, each as a respective component 340). However, the described techniques may include any quantity of components 440 in a stack, such as four components 440 (e.g., for an 8-high HBM or 3D stacked memory implementation), six components 440 (e.g., for a 12-high HBM or 3D stacked memory implementation), nine components 440 (e.g., for an 18-high HBM or 3D stacked memory implementation), or twelve components 440 (e.g., for a 24-high HBM or 3D stacked memory implementation) among other examples. In some examples, the eighth operations may include bonding (e.g., soldering) a stack of components 440 with a component 450, which may be an example of a die 205. In some examples, such a stack may be encapsulated, such as with an epoxy mold compound.

Thus, a system 400 may be fabricated to include a component 340-c that includes first circuitry and has one or more conductor portions 420 along a surface 302. Each of the conductor portions 420 may include a first material (e.g., a material of conductors 325) extending outward from the surface 302 (e.g., along a positive z-direction) and a second material (e.g., conductor material 415) in contact with the first material along a direction (e.g., the z-direction) from the surface 302. The system 400 may also be fabricated to include a component 340-d that includes second circuitry. The component 340-d may be bonded (e.g., in accordance with a fusion bonding, in accordance with a hybrid bonding) with the surface 406 of the component 340-c opposite the surface 302. The second circuitry may be electrically coupled with the first circuitry via one or more first conductive contacts (e.g., vias, contacts, bonding pads, or a combination thereof) of the component 340-c and one or more second conductive contacts (e.g., vias, contacts, bonding pads, or a combination thereof) of the component 340-d.

The system 400 may include one or more conductor portions 430 (e.g., vias 335) along the surface 302, which may be electrically coupled with the first circuitry. In some examples, each of the conductor portions 430 may include a third material (e.g., copper) that is different than the material of the contacts 325. The conductor portions 430 may be in contact with the conductors 325 of a conductor portion 420 and may extend inward (e.g., along the negative z-direction) from the surface 302. The system 400 may further include respective dielectric materials (e.g., dielectric material 305, dielectric material 310, bonding layers) associated with each component 340.

In some examples, by using the carrier 405, the adhesive material 410, or both, systems 400 may be fabricated with reduced complexity, thus reducing fabrication cost and increasing reliability of the system 400. For example, using the carrier may reduce surface preparation operations for a component 340, which may reduce particle debris and thereby reduce a probability of bonding defects. Additionally, reducing the fabrication complexity may reduce energy consumption of the fabrication process, which may enable a more efficient and more sustainable manufacture. Moreover, the described techniques may enable the carrier 405 to be reusable across multiple fabrication cycles. This use of recyclable carriers 405 may reduce material waste, thereby increasing fabrication efficiency and reducing adverse environmental impact of the fabrication process, among other benefits.

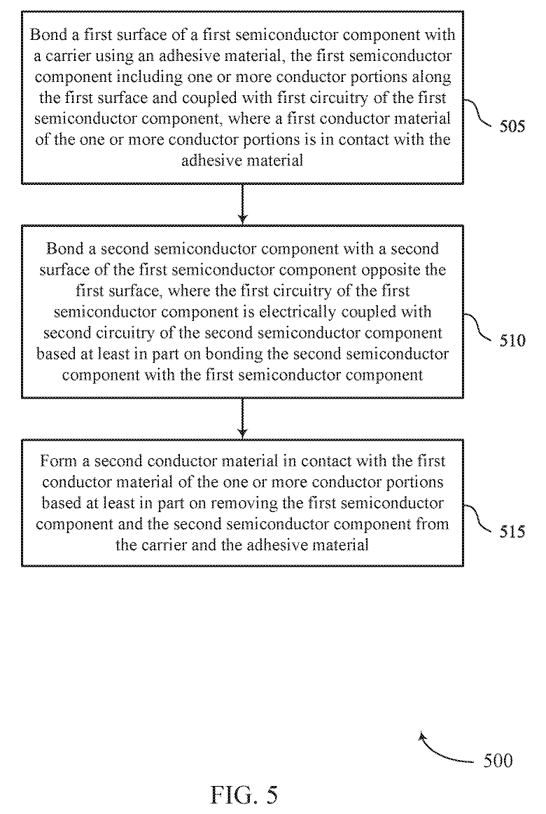

FIG. 5 shows a flowchart illustrating a method 500 that supports semiconductor stack formation with reusable carriers in accordance with examples as disclosed herein. The operations of method 500 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 505, the method 500 may include bonding a first surface of a first semiconductor component with a carrier using an adhesive material, the first semiconductor component including one or more conductor portions along the first surface and coupled with first circuitry of the first semiconductor component, where a first conductor material of the one or more conductor portions is in contact with the adhesive material.

At 510, the method 500 may include bonding a second semiconductor component with a second surface of the first semiconductor component opposite the first surface, where the first circuitry of the first semiconductor component is electrically coupled with second circuitry of the second semiconductor component based at least in part on bonding the second semiconductor component with the first semiconductor component.

At 515, the method 500 may include forming a second conductor material in contact with the first conductor material of the one or more conductor portions based at least in part on removing the first semiconductor component and the second semiconductor component from the carrier and the adhesive material.

In some examples, an apparatus (e.g., a manufacturing system) as described herein may perform a method or methods, such as the method 500. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for bonding a first surface of a first semiconductor component with a carrier using an adhesive material, the first semiconductor component including one or more conductor portions along the first surface and coupled with first circuitry of the first semiconductor component, where a first conductor material of the one or more conductor portions is in contact with the adhesive material; bonding a second semiconductor component with a second surface of the first semiconductor component opposite the first surface, where the first circuitry of the first semiconductor component is electrically coupled with second circuitry of the second semiconductor component based at least in part on bonding the second semiconductor component with the first semiconductor component; and forming a second conductor material in contact with the first conductor material of the one or more conductor portions based at least in part on removing the first semiconductor component and the second semiconductor component from the carrier and the adhesive material.

Aspect 2: The method or apparatus of aspect 1, where the first conductor material includes aluminum and the second conductor material includes solder.

Aspect 3: The method or apparatus of any of aspects 1 through 2, where the carrier includes a glass material.

Aspect 4: The method or apparatus of any of aspects 1 through 3, including operations, features, circuitry, logic, means, or instructions, or any combination thereof that refrain from forming a bonding layer at the first surface of the first semiconductor component, where bonding the first semiconductor component with the carrier is based at least in part on an absence of the bonding layer at the first surface.

Aspect 5: The method or apparatus of any of aspects 1 through 4, further including operations, features, circuitry, logic, means, or instructions, or any combination thereof for performing an edge trim operation to remove a portion of the first semiconductor component before bonding the first semiconductor component with the carrier.

Aspect 6: The method or apparatus of aspect 5, further including operations, features, circuitry, logic, means, or instructions, or any combination thereof for performing a second edge trim operation to remove a portion of the second semiconductor component after removing the first semiconductor component and the second semiconductor component from the carrier and the adhesive material.

Aspect 7: The method or apparatus of any of aspects 1 through 6, where bonding the first surface of the first semiconductor component with the carrier includes a thermocompression bonding of the first surface with the adhesive material.

Aspect 8: The method or apparatus of any of aspects 1 through 7, further including operations, features, circuitry, logic, means, or instructions, or any combination thereof for removing a portion of the first semiconductor component to expose one or more vias along the second surface, where bonding the second semiconductor component with the first semiconductor component is based at least in part on a coupling with the one or more vias.

Aspect 9: The method or apparatus of any of aspects 1 through 8, further including operations, features, circuitry, logic, means, or instructions, or any combination thereof for bonding, after removing the first semiconductor component and the second semiconductor component from the carrier, the carrier with a third semiconductor component using a second adhesive material.

Aspect 10: The method or apparatus of any of aspects 1 through 9, including operations, features, circuitry, logic, means, or instructions, or any combination thereof that refrain from performing an edge trim operation on the carrier after bonding the first semiconductor component with the carrier.

Aspect 11: The method or apparatus of any of aspects 1 through 10, where the second surface of the first semiconductor component includes a first dielectric material over a back side of the first semiconductor component; a third surface of the second semiconductor component includes a second dielectric material over a front side of the second semiconductor component; and bonding the second semiconductor component with the first semiconductor component is based at least in part on a fusion of the first dielectric material at the second surface of the first semiconductor component with the second dielectric material at the third surface of the second semiconductor component.

Aspect 12: The method or apparatus of any of aspects 1 through 11, where the second semiconductor component includes one or more second conductor portions including the first conductor material along a fourth surface of the second semiconductor component opposite a third surface that is bonded with the first semiconductor component.

Aspect 13: The method or apparatus of any of aspects 1 through 12, where the first semiconductor component is associated with a first wafer including a plurality of first semiconductor components and the second semiconductor component is associated with a second wafer including a plurality of second semiconductor components and bonding the second semiconductor component with the first semiconductor component is based at least in part on bonding the first wafer with the second wafer.

Aspect 14: The method or apparatus of any of aspects 1 through 13, where the first circuitry includes first memory array circuitry and the second circuitry includes second memory array circuitry.

It should be noted that the aspects described herein describe possible implementations, and that the operations and the steps may be rearranged or otherwise modified and that other implementations are possible. Further, portions from two or more of the methods may be combined.

An apparatus (e.g., a semiconductor apparatus, a semiconductor system) is described. The following provides an overview of aspects of the apparatus as described herein:

Aspect 15: A semiconductor system, including: a first semiconductor component including first circuitry and having one or more conductor portions along a first surface of the first semiconductor component, each of the one or more conductor portions including a first material extending outward from the first surface and a second material in contact with the first material along a direction from the first surface; and a second semiconductor component including second circuitry, the second semiconductor component bonded with a second surface of the first semiconductor component opposite the first surface, the second circuitry electrically coupled with the first circuitry via one or more first conductive contacts of the first semiconductor component and one or more second conductive contacts of the second semiconductor component.

Aspect 16: The semiconductor system of aspect 15, further including: one or more second conductor portions along the first surface and electrically coupled with the first circuitry, each of the one or more second conductor portions including a third material, different than the first material, in contact with the first material of a respective one of the one or more conductor portions and extending inward from the first surface.

Aspect 17: The semiconductor system of aspect 16, where: the first material includes aluminum; the second material includes solder; and the third material includes copper.

Aspect 18: The semiconductor system of any of aspects 15 through 17, where: the first surface is associated with a front side of the first semiconductor component and the second surface is associated with a back side of the first semiconductor component, the second semiconductor component has a third surface associated with a front side of the second semiconductor component and a fourth surface associated with a back side of the second semiconductor component, and the second semiconductor component is bonded with the first semiconductor component along the third surface.

Aspect 19: The semiconductor system of any of aspects 15 through 18, further including: a first dielectric material at the second surface of the first semiconductor component; and a second dielectric material at a surface of the second semiconductor component bonded with the second surface.

Aspect 20: The semiconductor system of aspect 19, where the bonding of the second semiconductor component with the first semiconductor component is based at least in part on a fusion of the first dielectric material with the second dielectric material.

Aspect 21: The semiconductor system of any of aspects 15 through 20, where the second semiconductor component further includes: one or more second conductor portions including the first material, the one or more second conductor portions along a second surface of the second semiconductor component opposite a first surface of the second semiconductor component that is bonded with the first semiconductor component.

Aspect 22: The semiconductor system of any of aspects 15 through 21, where the first circuitry includes first memory array circuitry and the second circuitry includes second memory array circuitry.

An apparatus (e.g., a semiconductor apparatus, a semiconductor system) is described. The following provides an overview of aspects of the apparatus as described herein:

Aspect 23: A semiconductor system formed by a process including: bonding a first surface of a first semiconductor component with a carrier using an adhesive material, the first semiconductor component including one or more conductor portions along the first surface and coupled with first circuitry of the first semiconductor component, where a first conductor material of the one or more conductor portions is in contact with the adhesive material; bonding a second semiconductor component with a second surface of the first semiconductor component opposite the first surface, where the first circuitry of the first semiconductor component is electrically coupled with second circuitry of the second semiconductor component based at least in part on bonding the second semiconductor component with the first semiconductor component; and forming a second conductor material in contact with the first conductor material of the one or more conductor portions based at least in part on removing the first semiconductor component and the second semiconductor component from the carrier and the adhesive material.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three-dimensional structure where two dimensions are greater than a third, e.g., a thin-film. Layers or levels may include different elements, components, or materials. In some examples, one layer or level may be composed of two or more sublayers or sublevels.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Some examples and operations described herein may be described with reference to sides of a semiconductor component. For example, a side of a semiconductor component may be referred to as a “back side” or “back,” or a “front side” or “front.” A front side of a semiconductor component may refer to a side (e.g., relative to a semiconductor substrate, such as a crystalline silicon substrate) that includes components such as transistors and capacitors. The front side may also include an electrically conductive metallization structure with chip contact areas. The front side may include FEOL, MOL, and BEOL layers. The front side may face up during at least some manufacturing processes and may include operative circuitry for the device’s operation (e.g., a side from which a substrate is doped to form transistor and other circuitry). In some examples, a back side of a semiconductor component may refer to a side (e.g., relative to the semiconductor substrate) that is opposite from at least some of the functional circuitry of the semiconductor component. A back side may be used for various supporting functions that complement the front side. For example, a back side of a semiconductor component may be bonded with a carrier while operations are performed on a front side, such as doping and metallization operations.

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method of semiconductor system formation, comprising:
bonding a first surface of a first semiconductor component with a carrier using an adhesive material, the first semiconductor component comprising one or more conductor portions along the first surface and coupled with first circuitry of the first semiconductor component, wherein a first conductor material of the one or more conductor portions is in contact with the adhesive material;
bonding a second semiconductor component with a second surface of the first semiconductor component opposite the first surface, wherein the first circuitry of the first semiconductor component is electrically coupled with second circuitry of the second semiconductor component based at least in part on bonding the second semiconductor component with the first semiconductor component; and
forming a second conductor material in contact with the first conductor material of the one or more conductor portions based at least in part on removing the first semiconductor component and the second semiconductor component from the carrier and the adhesive material.

2. The method of claim 1, wherein:
the first conductor material comprises aluminum; and
the second conductor material comprises solder.

3. The method of claim 1, wherein the carrier comprises a glass material.

4. The method of claim 1, further comprising:
refraining from forming a bonding layer at the first surface of the first semiconductor component, wherein bonding the first semiconductor component with the carrier is based at least in part on an absence of the bonding layer at the first surface.

5. The method of claim 1, further comprising:
performing an edge trim operation to remove a portion of the first semiconductor component before bonding the first semiconductor component with the carrier.

6. The method of claim 5, further comprising:
performing a second edge trim operation to remove a portion of the second semiconductor component after removing the first semiconductor component and the second semiconductor component from the carrier and the adhesive material.

7. The method of claim 1, wherein bonding the first surface of the first semiconductor component with the carrier comprises a thermocompression bonding of the first surface with the adhesive material.

8. The method of claim 1, further comprising:
removing a portion of the first semiconductor component to expose one or more vias along the second surface, wherein bonding the second semiconductor component with the first semiconductor component is based at least in part on a coupling with the one or more vias.

9. The method of claim 1, further comprising:
bonding, after removing the first semiconductor component and the second semiconductor component from the carrier, the carrier with a third semiconductor component using a second adhesive material.

10. The method of claim 1, further comprising:
refraining from performing an edge trim operation on the carrier after bonding the first semiconductor component with the carrier.

11. The method of claim 1, wherein:
the second surface of the first semiconductor component comprises a first dielectric material over a back side of the first semiconductor component;
a third surface of the second semiconductor component comprises a second dielectric material over a front side of the second semiconductor component; and
bonding the second semiconductor component with the first semiconductor component is based at least in part on a fusion of the first dielectric material at the second surface of the first semiconductor component with the second dielectric material at the third surface of the second semiconductor component.

12. The method of claim 1, wherein the second semiconductor component comprises one or more second conductor portions comprising the first conductor material along a fourth surface of the second semiconductor component opposite a third surface that is bonded with the first semiconductor component.

13. The method of claim 1, wherein:
the first semiconductor component is associated with a first wafer comprising a plurality of first semiconductor components and the second semiconductor component is associated with a second wafer comprising a plurality of second semiconductor components, and
bonding the second semiconductor component with the first semiconductor component is based at least in part on bonding the first wafer with the second wafer.

14. The method of claim 1, wherein the first circuitry comprises first memory array circuitry and the second circuitry comprises second memory array circuitry.

15. A semiconductor system, comprising:
a first semiconductor component comprising first circuitry and having one or more conductor portions along a first surface of the first semiconductor component, each of the one or more conductor portions comprising a first material extending outward from the first surface and a second material in contact with the first material along a direction from the first surface; and
a second semiconductor component comprising second circuitry, the second semiconductor component bonded with a second surface of the first semiconductor component opposite the first surface, the second circuitry electrically coupled with the first circuitry via one or more first conductive contacts of the first semiconductor component and one or more second conductive contacts of the second semiconductor component.

16. The semiconductor system of claim 15, further comprising:
one or more second conductor portions along the first surface and electrically coupled with the first circuitry, each of the one or more second conductor portions comprising a third material, different than the first material, in contact with the first material of a respective one of the one or more conductor portions and extending inward from the first surface.

17. The semiconductor system of claim 16, wherein:
the first material comprises aluminum;
the second material comprises solder; and
the third material comprises copper.

18. The semiconductor system of claim 15, wherein:
the first surface is associated with a front side of the first semiconductor component and the second surface is associated with a back side of the first semiconductor component,
the second semiconductor component has a third surface associated with a front side of the second semiconductor component and a fourth surface associated with a back side of the second semiconductor component, and
the second semiconductor component is bonded with the first semiconductor component along the third surface.

19. The semiconductor system of claim 15, further comprising:
a first dielectric material at the second surface of the first semiconductor component; and
a second dielectric material at a surface of the second semiconductor component bonded with the second surface.

20. The semiconductor system of claim 19, wherein the bonding of the second semiconductor component with the first semiconductor component is based at least in part on a fusion of the first dielectric material with the second dielectric material.

21. The semiconductor system of claim 15, wherein the second semiconductor component further comprises:
one or more second conductor portions comprising the first material, the one or more second conductor portions along a second surface of the second semiconductor component opposite a first surface of the second semiconductor component that is bonded with the first semiconductor component.

22. The semiconductor system of claim 15, wherein the first circuitry comprises first memory array circuitry and the second circuitry comprises second memory array circuitry.

23. A semiconductor system formed by a process comprising:
bonding a first surface of a first semiconductor component with a carrier using an adhesive material, the first semiconductor component comprising one or more conductor portions along the first surface and coupled with first circuitry of the first semiconductor component, wherein a first conductor material of the one or more conductor portions is in contact with the adhesive material;
bonding a second semiconductor component with a second surface of the first semiconductor component opposite the first surface, wherein the first circuitry of the first semiconductor component is electrically coupled with second circuitry of the second semiconductor component based at least in part on bonding the second semiconductor component with the first semiconductor component; and
forming a second conductor material in contact with the first conductor material of the one or more conductor portions based at least in part on removing the first semiconductor component and the second semiconductor component from the carrier and the adhesive material.
